(19) United States
(12) Patent Application Publication
(10) Pub. No.: US 2018/0094110 A1
(43) Pub. Date: Apr. 5, 2018

(54) GLASS CLOTH

(71) Applicant: ASAHI KASEI KABUSHIKI KAISHA, Tokyo (JP)

(72) Inventors: Kenichi NAKANISHI, Tokyo (JP); Shinichiro TACHIBANA, Tokyo (JP); Makoto SOMEYA, Tokyo (JP)

(73) Assignee: ASAHI KASEI KABUSHIKI KAISHA, Tokyo (JP)

(21) Appl. No.: 15/569,558

(22) PCT Filed: Apr. 27, 2016
(86) PCT No.: PCT/JP2016/063225

§ 371 Date: Oct. 26, 2017

(30) Foreign Application Priority Data
Apr. 27, 2015 (JP) 2015-090518
Jul. 14, 2015 (JP) 2015-140410
Jan. 6, 2016 (JP) 2016-001188

(51) Int. Cl. C08J 5/24; C03C 13/00; D06M 13/513; C03C 25/10; D03D 15/00; D03D 15/12; D03D 1/00; H05K 1/03

(52) U.S. Cl. CPC C08J 5/24; C03C 13/00; D06M 13/513; C03C 25/10; D03D 15/0011; H05K 1/024; D03D 1/0082; H05K 1/0366; D03D 2700/0148; H05K 2201/029; D03D 15/12

(57) ABSTRACT

A glass cloth obtained by weaving a glass yarn including a plurality of glass filaments, wherein the compositional amount of B₂O₃ is 20% by mass to 30% by mass in the glass filaments and the compositional amount of SiO₂ is 50% by mass to 60% by mass in the glass filaments, and the loss on ignition of the glass cloth is 0.25% by mass to 1.0% by mass.

### TECHNICAL FIELD

The present invention relates to a glass cloth.

### BACKGROUND ART

Currently, as information terminals such as a smartphone are improved in performance and increased in the communication speed thereof, a printed wiring board to be used is remarkably advanced in terms of a reduction in dielectric constant and a reduction in dielectric dissipation factor.

As an insulating material for the printed wiring board, a laminate is widely used which is obtained by impregnating a glass cloth with a thermosetting resin (hereinafter, referred to as “matrix resin”.) such as an epoxy resin to provide a prepreg, stacking such a prepreg, and subjecting the resultant to heating, pressurizing and curing. While the dielectric constant of a matrix resin for use in the substrate for high-speed communication is about 3, the dielectric constant of a common E glass cloth is about 6.7, and the problem of a high dielectric constant in lamination is being exposed.

Therefore, a low-dielectric glass cloth of D glass, NE glass, L glass or the like different from E glass in composition is proposed. In general, the amounts of SiO₂ and B₂O₃ to be compounded in glass composition are required to be increased for a reduction in dielectric constant.

In particular, the amount of B₂O₃ to be compounded is increased, resulting in a reduction in glass melting viscosity, to allow a glass yarn to be easily produced. In addition, the glass melting viscosity is reduced, resulting in a decrease in the amount of an air bubble in the glass yarn (hereinafter, referred to as “hollow yarn”.) generated in spinning of the glass yarn. The hollow yarn is an important factor which largely affects insulation reliability degradation of a substrate.

The amount of B₂O₃ to be compounded, however, is increased to thereby cause the problem of an increase in the amount of moisture absorption of glass. The amount of moisture absorption of glass is a factor which extremely largely affects insulation reliability degradation of a substrate, and thus largely affects insulation reliability degradation of a substrate even in consideration of a decrease in the amount of the hollow yarn. Therefore, most glass compositions heretofore actually applied to a glass cloth for a printed wiring board have an amount of B_{2O3} to be compounded of 20% or less (see, for example, Patent Literature 1).

### CITATION LIST

### Patent Literature

[Patent Literature 1] Japanese Patent Laid-Open No. S63-2831

[Patent Literature 2] Japanese Patent No. 4269194

### SUMMARY OF INVENTION

### Technical Problem

If the amount of B₂O₃ to be compounded is 20% or less, however, there are the problems of insulation reliability degradation due to an increase in the amount of a hollow yarn, and of an increase in dielectric constant. Therefore, it is difficult to produce a glass cloth satisfying all requirements including a reduction in dielectric constant, an enhancement in insulation reliability owing to a decrease in the amount of a hollow yarn, and an enhancement in insulation reliability owing to an enhancement in moisture absorption resistance.

In order to reduce such problems, a treatment of the surface of a glass cloth with an optimal silane coupling agent is considered to be effective. If a printed wiring board provided with a glass cloth merely treated with a silane coupling agent, however, is processed by a carbon dioxide laser widely used for processing of a printed wiring board, the interface between a glass yarn and a matrix resin is easily peeled, and it is thus difficult to achieve sufficient insulation reliability in high-density wiring.

The present invention has been made in view of the above problems, and an object thereof is to provide a glass cloth which is thin and low in dielectric constant and which can satisfy both of an enhancement in insulation reliability owing to a decrease in the amount of a hollow yarn and an enhancement in insulation reliability owing to an enhancement in moisture absorption resistance, and a prepreg and a printed wiring board using the glass cloth.

Another object of the present invention is to provide a glass cloth which can afford a laminate having a low dielectric constant, excellent carbon dioxide laser processability and high insulation reliability, and which has few hollow yarns, as well as a prepreg obtained from the glass cloth and a printed wiring board obtained from the prepreg.

### Solution to Problem

The present inventors have made intensive studies in order to solve the above problems, and as a result, have found that the above problems can be solved by allowing a predetermined compositional amount of B₂O₃ and a predetermined compositional amount of SiO₂ to be included to thereby achieve a low dielectric constant and an excellent hollow yarn quality, and by allowing the loss on ignition of a glass cloth to fall within a predetermined range, thereby leading to completion of the present invention.

That is, the present invention is as follows.

[1]

A glass cloth obtained by weaving a glass yarn comprising a plurality of glass filaments, wherein a compositional amount of B₂O₃ is 20% by mass to 30% by mass in the glass filaments and a compositional amount of SiO₂ is 50% by mass to 60% by mass in the glass filaments, and a loss on ignition of the glass cloth is 0.25% by mass to 1.0% by mass.

[2]

The glass cloth according to [1], wherein the loss on ignition of the glass cloth is 0.3% by mass to 0.9% by mass.

[3]

The glass cloth according to [1] or [2], wherein the loss on ignition of the glass cloth is 0.35% by mass to 0.8% by mass.

[4]

The glass cloth according to [1], wherein an average filament diameter of the glass filaments is 5 μm or less, and the loss on ignition of the glass cloth is 0.5% by mass to 1.0% by mass.

[5]

The glass cloth according to any one of [1] to [4], wherein an air permeability of the glass cloth is 50 cm³/cm²/sec or less.

[6]

The glass cloth according to any one of [1] to [5], wherein a tensile strength of the glass cloth is 20 N/inch or more.

[7]

The glass cloth according to any one of [1] to [6], wherein an amount of carbon on the glass cloth is 1 mol/cm² or more.

[8]

The glass cloth according to any one of [1] to [7], wherein the glass cloth is subjected to a surface-treatment with a silane coupling agent represented by the following general formula (1):

X(R)₃₋ₙSiYₙ (1)

wherein X represents an organic functional group having one or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.
[9]

The glass cloth according to any one of [1] to [7], wherein the glass cloth is subjected to a surface-treatment with a silane coupling agent represented by the following general formula (2):

X(R)₃₋ₙSiYₙ (2)

wherein X represents an organic functional group having three or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.
[10]

The glass cloth according to any one of [1] to [7], wherein the glass cloth is subjected to a surface-treatment with a silane coupling agent represented by the following general formula (3):

X(R)₃₋ₙSiYₙ (3)

wherein X represents an organic functional group having four or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.
[11]

A prepreg comprising the glass cloth according to any one of [1] to [10], and a matrix resin with which the glass cloth is impregnated.

[12]

A printed wiring board produced by use of the prepreg according to [5].

### Advantageous Effects of Invention

The present invention can provide a glass cloth which is thin and low in dielectric constant, and which can allow a prepreg and a printed wiring board excellent in insulation reliability, or a substrate for such laminates (hereinafter, simply also referred to as “substrate”) to be produced, as well as a prepreg and a printed wiring board using the glass cloth.

The present invention can also provide a glass cloth which can afford a laminate having a low dielectric constant, excellent carbon dioxide laser processability and high insulation reliability, and which has few hollow yarns, as well as a prepreg obtained from the glass cloth and a printed wiring board obtained from the prepreg.

### DESCRIPTION OF EMBODIMENTS

Hereinafter, an embodiment (hereinafter, referred to as “the present embodiment”.) of the present invention is described in detail, but the present invention is not intended to be limited thereto, and various modifications can be made without departing from the gist of the present invention.

### [Glass Cloth]

A glass cloth of the present embodiment is a glass cloth obtained by weaving a glass yarn including a plurality of glass filaments, wherein the compositional amount of B₂O₃ is 20% by mass to 30% by mass in the glass filaments and the compositional amount of SiO₂ is 50% by mass to 60% by mass in the glass filaments, and the loss on ignition of the glass cloth is 0.25% by mass to 1.0% by mass.

Such a glass cloth is used to thereby allow a substrate obtained to have a more reduced dielectric constant and more enhanced insulation reliability than a substrate obtained by use of a common glass cloth of E glass composition.

The compositional amount of B₂O₃ in the glass filaments is 20% by mass to 30% by mass, preferably 21% by mass to 27% by mass, more preferably 21% by mass to 25% by mass. The compositional amount of B₂O₃ is 20% by mass or more, resulting in a reduction in glass melting viscosity and easy spinning of the glass yarn, to thereby enable hollow yarn quality of the glass cloth to be stabilized, and result in a reduction in dielectric constant. In addition, the compositional amount of B₂O₃ is 30% by mass or less, resulting in a more enhancement in moisture absorption resistance in the case of performing of surface treatment. On the other hand, if the compositional amount of B₂O₃ is less than 20% by mass, the number of hollow yarns is increased, and insulation reliability is accordingly degraded. In addition, if the compositional amount of B₂O₃ is decreased to the compositional amount of E glass, the number of hollow yarns tends to be decreased, but the dielectric constant is increased. In addition, if the compositional amount of B₂O₃ is more than 30% by mass, the amount of moisture absorption is increased to thereby cause insulation reliability to be degraded. The compositional amount of B₂O₃ can be adjusted depending on the amount of raw materials for use in production of the glass filaments.

In addition, the compositional amount of SiO₂ in the glass filaments is 50% by mass to 60% by mass, preferably 50% by mass to 58% by mass, more preferably 51% by mass to 56% by mass. The compositional amount of SiO₂ is 50% or more, resulting in a reduction in dielectric constant of a substrate obtained. In addition, the compositional amount of SiO₂ is 60% or less, resulting in more enhancements in carbon dioxide laser processability and drillability of a substrate obtained. The compositional amount of SiO₂ can be adjusted depending on the amount of raw materials for use in production of the glass filaments.

The glass filaments may also have any composition other than B₂O₃ and SiO₂. Examples of such other composition include, but are not particularly limited to, Al₂O₃, CaO and MgO.

The compositional amount of Al₂O₃ in the glass filaments is preferably 11% by mass to 16% by mass, more preferably 12% by mass to 16% by mass. The compositional amount of Al₂O₃ is within the above range to result in a tendency to more enhance yarn productivity.

The compositional amount of CaO in the glass filaments is preferably 4% by mass to 8% by mass, more preferably 6% by mass to 8% by mass. The compositional amount of CaO is within the above range to result in a tendency to more enhance yarn productivity.

The average filament diameter of the glass filaments is preferably 2.5 to 9.0 μm, more preferably 2.5 to 7.0 μm, further preferably 3.5 to 7.0 μm, still further preferably 3.5 to 5.0 μm, particularly preferably 3.5 to 4.5 μm. The average filament diameter of the glass filaments is within the above range, resulting in a tendency to more enhance processability in processing by a mechanical drill, a carbon dioxide laser, or an UV-YAG laser, of a substrate obtained. Therefore, a thin and high-density mounting printed wiring board can be realized. In particular, when the average diameter is 5 μm or less, the contact area per unit volume of the matrix resin and the glass filaments is increased, resulting in a tendency to largely exert the effect by a loss on ignition of 0.25% or more, described below.

The beating densities of the warp yarn and the weft yarn forming the glass cloth is preferably 10 to 120/inch, more preferably 40 to 100/inch, further preferably 40 to 100/inch.

In addition, the weight (basis weight) of the glass cloth is preferably 8 to 250 g/m², more preferably 8 to 100 g/m², further preferably 8 to 50 g/m², particularly preferably 8 to 35 g/m².

Examples of the weave structure of the glass cloth include, but are not particularly limited to, weave structures such as plain weave, basket weave, sateen weave and twill weave structures. Among them, a plain weave structure is more preferable.

The glass cloth (glass filaments) is preferably subjected to a surface-treatment with a surface treatment agent. Examples of the surface treatment agent include, but are not particularly limited to, a silane coupling agent. The amount of the glass cloth to be treated with the surface treatment agent can be estimated from the following loss on ignition.

The loss on ignition of the glass cloth is 0.25% by mass to 1.0% by mass, preferably 0.3% by mass to 0.9% by mass, more preferably 0.35% by mass to 0.8% by mass.

The loss on ignition of the glass cloth is 0.25% by mass or more, thereby imparting sufficient reactivity with the matrix resin in production of a substrate, and also imparting a more enhancement in moisture absorption resistance to result in a more enhancement in insulation reliability. In addition, the loss on ignition of the glass cloth is 1.0% by mass or less, resulting in a more enhancement in impregnation property of the glass cloth with the resin. The present invention is here directed to a glass cloth including a continuous glass long fiber. A glass filler, a glass particle, a glass powder and the like are not required to have the loss on ignition of the present invention because the resin/glass interface is not continuous and thus short, and therefore moisture absorption at the interface hardly leads to insulation failure of a substrate and excellent impregnation property with the resin is not also required. The “loss on ignition” here can be measured according to a method described in JIS R3420. That is, the glass cloth is first placed in a dryer at 105° C.±5° C., and dried for at least 30 minutes. After such drying, the glass cloth is transferred to a desiccator, and cooled to room temperature. After such cooling, the glass cloth is weighed in a unit of 0.1 mg or less. Next, the glass cloth is heated in a muffle furnace at 625±20° C. or at 500 to 600° C. In the case of 625±20° C., such heating is conducted for 10 minutes or more, and in the case of 500 to 600° C., such heating is conducted for 1 hour or more. After heating in the muffle furnace, the glass cloth is transferred to a desiccator, and cooled to room temperature. After such cooling, the glass cloth is weighed in a unit of 0.1 mg or less. The loss on ignition determined according to the above measurement method is used to thereby define the amount of the glass cloth to be treated with the silane coupling agent.

In the present embodiment, the glass cloth is first placed in a dryer at 110° C., and dried for 60 minutes. After such drying, the glass cloth is transferred to a desiccator, left to stand for 20 minutes, and cooled to room temperature. After such cooling, the glass cloth is weighed in a unit of 0.1 mg or less. Next, the glass cloth is heated in a muffle furnace at 625° C. for 20 minutes. After heating in the muffle furnace, the glass cloth is transferred to a desiccator, left to stand for 20 minutes, and cooled to room temperature. After such cooling, the glass cloth is weighed in a unit of 0.1 mg or less. The loss on ignition determined according to the above measurement method is used to thereby define the amount of the glass cloth to be treated with the silane coupling agent.

In particular, when the average filament diameter of the glass filaments is 5 μm or less, the loss on ignition of the glass cloth is preferably 0.5 to 1.0% by mass. In addition, when the average filament diameter of the glass filaments is 4.5 μm or less, the loss on ignition of the glass cloth is preferably 0.6% by mass to 1.0% by mass, and furthermore, when the average filament diameter of the glass filaments is 4 μm or less, the loss on ignition of the glass cloth is preferably 0.6% by mass to 1.0% by mass. The loss on ignition, depending on the average filament diameter of the glass filaments, is within the above range, thereby increasing the contact area per unit volume of the matrix resin and the glass filaments, to result in a tendency to largely exert the effect by a loss on ignition of 0.25% or more, described below.

As the silane coupling agent, a silane coupling agent represented by the following general formula (1), a silane coupling agent represented by the following general formula (2), or a silane coupling agent represented by the following general formula (3) is preferably used, but is not particularly limited thereto. Such a silane coupling agent is used, thereby more enhancing moisture absorption resistance to result in a tendency to more enhance insulation reliability. In a method for producing the glass cloth, when the glass cloth is coated with the silane coupling agent, such coating is preferably made with a treatment liquid (hereinafter, simply referred to as “treatment liquid”.) where the silane coupling agent is dissolved or dispersed in a solvent:

X(R)₃₋ₙSiYₙ (1)

wherein X represents an organic functional group having one or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group;

X(R)₃₋ₙSiYₙ (2)

wherein X represents an organic functional group having three or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group; and

X(R)₃₋ₙSiYₙ (3)

wherein X represents an organic functional group having four or more of at least any of an amino group and an unsaturated double bond groups, each Y independently represents an alkoxy group, n represents an integer of 1 or more and 3 or less, and each R independently represents a group selected from the group consisting of a methyl group, an ethyl group and a phenyl group.

In general formulae (1) to (3), X more preferably represents an organic functional group having three or more of at least any of an amino group and an unsaturated double bond group, and further preferably represents an organic functional group having four or more of at least any of amino groups and unsaturated double bond groups. X represents such a functional group, thereby resulting in a tendency to more enhance moisture absorption resistance.

In general formulae (1) to (3), any type of alkoxy group can be used as the alkoxy group, but an alkoxy group having 5 or less carbon atoms is preferable for the purpose of stable treatment of the glass cloth.

Examples of the silane coupling agent that can be specifically used include, but are not particularly limited to, known single substances such as N-β-(N-vinylbenzylaminoethyl)-γ-aminopropyltrimethoxysilane and hydrochloride thereof, N-β-(N-vinylbenzylaminoethyl)-γ-aminopropylmethyldimethoxysilane and hydrochloride thereof, N-β-(N-di(vinylbenzyl)aminoethyl)-γ-aminopropyltrimethoxysilane and hydrochloride thereof, N-β-(N-di(vinylbenzyl)aminoethyl)-N-γ-(N-vinylbenzyl)-γ-aminopropyltrimethoxysilane and hydrochloride thereof, aminopropyltrimethoxysilane, vinyltrimethoxysilane, methacryloxypropyltrimethoxysilane and acryloxypropyltrimethoxysilane, or mixtures thereof.

As the solvent for dissolving or dispersing the silane coupling agent, any of water or any organic solvent can be used, and water preferably serves as a main solvent in terms of safety and global environmental protection. The method for providing a treatment liquid whose main solvent is water is preferably any method of a method where the silane coupling agent is directly loaded into water, and a method where the silane coupling agent is dissolved in a water-soluble organic solvent to provide a solution in the organic solvent, and thereafter the solution in the organic solvent is loaded into water.

A surfactant can also be used in combination in order to enhance water dispersibility and stability of the silane coupling agent in the treatment liquid.

The air permeability of the glass cloth is preferably 50 cm³/cm²/sec or less, more preferably 40 cm³/cm²/sec or less, further preferably 30 cm³/cm²/sec or less, still further preferably 20 cm³/cm²/sec or less, particularly preferably 10 cm³/cm²/sec or less. The air permeability of the glass cloth is 50 cm³/cm²/sec or less, thereby enhancing difficulty of permeation of a plating, to result in a tendency to more enhance carbon dioxide laser processability and insulation reliability of a substrate obtained. Such difficulty of permeation of a plating varies depending on not only the air permeability, but also the composition of the glass filaments, and a glass filament having the composition of the present embodiment tends to be relatively high in ease of permeation of a plating as compared with a glass filament lower in the compositional amount of B₂O₃. The air permeability, however, is within the above range, thereby making it possible to provide a glass cloth which has difficulty in permeation of a plating and which is excellent in carbon dioxide laser processability and insulation reliability with characteristics of the glass filaments having the composition of the present embodiment being kept. In addition, the lower limit of the air permeability of the glass cloth is not particularly limited, and is preferably 0 cm³/cm²/sec or more. The “air permeability” here can be measured according to a method described in JIS R3420. Specifically, a manual or automatic Frajour type testing machine is used as a mechanical instrument for testing. A glass cloth test piece is placed on one end of a cylinder, pressed by a clamp, and mounted. In the case where a manual type testing machine is used, air is sucked so that the pressure indicated by a gradient-type oil pressure meter with a rheostat is 124.5 Pa, and the amount (cm³/cm²/sec) of air passing through the test piece is determined from the pressure indicated by a vertical-type oil pressure meter in adjustment of a suction fan, and the type of an air hole used.

The air permeability of the glass cloth can be decreased by fiber-opening processing of the glass cloth. In other words, the air permeability can be decreased depending on the degree of fiber-opening. Examples of the fiber-opening processing method include, but are not particularly limited to, a method of fiber-opening the glass cloth by spray water (fiber-opening by high-pressure water), a vibrowasher, ultrasonic water, mangle, or the like. In particular, the air permeability can be more effectively decreased by conducting fiber-opening by high-pressure water with the process tension in such processing being decreased.

The tensile strength of the glass cloth is preferably 20 N/inch or more, more preferably 30 N/inch or more, further preferably 40 N/inch or more. When strong fiber-opening by high-pressure water is conducted in order that the air permeability is 50 cm³/cm²/sec or less, the tensile strength of the glass cloth tends to be lower. In the case of a glass cloth where the compositional amount of B₂O₃ is 20% by mass to 30% by mass and the compositional amount of SiO₂ is 50% by mass to 60% by mass, the tensile strength is 20 N/inch or more, thereby resulting in a tendency to remarkably hardly cause cutting (fuzz) of the glass filaments. The fuzz is protruded in substrate production, and brought into contact with a conductor section such as copper foil, thereby resulting in a tendency to considerably degrade insulation reliability in the Z-direction of a substrate. Therefore, the tensile strength is 20 N/inch or more, thereby resulting in a tendency to more enhance insulation reliability in the Z-direction of a substrate obtained.

The tensile strength of the glass cloth can be measured according to Section 7.4 of JIS R 3420.

The amount of carbon on the glass cloth is preferably 1 mol/cm² or more. The amount of carbon on the glass cloth is 1 mol/cm² or more, thereby increasing the effect of protecting the surface of the glass cloth to result in a tendency to enhance insulation reliability.

### [Method for Producing Glass Cloth]

Examples of a method for producing the glass cloth of the present embodiment include, but are not particularly limited to, a method including a covering step of almost completely covering a glass filament surface with the silane coupling agent by a treatment liquid having a concentration of 0.1 to 3.0% by weight, a fixing step of fixing the silane coupling agent to the glass filament surface by heating and drying, and an adjustment step of washing at least a part of the silane coupling agent fixed to the glass filament surface, with high-pressure spray water or the like, to thereby adjust the amount of the silane coupling agent attached so that the loss on ignition ranges from 0.25% by mass to 1.0% by mass. In addition, the covering step, the fixing step and the adjustment step may be subjected to the glass yarn before a weaving step of weaving the glass yarn to provide the glass cloth, or subjected to the glass cloth after the weaving step. Furthermore, there may be, if necessary, included, after the weaving step, a fiber-opening step of fiber-opening the glass yarn of the glass cloth, a heating/desizing step of heating and desizing the glass cloth, or the like. In the case where the adjustment step is performed after the weaving step, the adjustment step may combine with the fiber-opening step. The composition of the glass cloth is not here changed before and after fiber-opening.

It is considered that the above production method can almost completely and uniformly form a silane coupling agent layer on the entire surface of each filament of the glass filaments forming the glass yarn.

As the method for coating the glass cloth with the treatment liquid, (i) a method where the treatment liquid is received in a bath and the glass cloth is dipped therein and allowed to pass therethrough (hereinafter, referred to as “dipping method”.), (ii) a method where the glass cloth is directly coated with the treatment liquid by a roll coater, a die coater, a gravure coater or the like, or the like can be adopted. When such coating is conducted by the dipping method (i), the dipping time of the glass cloth in the treatment liquid is selected to be 0.5 seconds or more and 1 minute or less.

Examples of the method where the glass cloth is coated with the treatment liquid and thereafter the solvent is subjected to heating and drying include a known method by hot air, electromagnetic wave, or the like.

The heating and drying temperature is preferably 90° C. or more, more preferably 100° C. or more so that the reaction of the silane coupling agent with glass is sufficiently performed. In addition, the temperature is preferably 300° C. or less, more preferably 200° C. or less in order to prevent the organic functional group of the silane coupling agent from being degraded.

The fiber-opening method in the fiber-opening step is not particularly limited, and examples thereof include a method where the glass cloth is subjected to fiber-opening processing by spray water (fiber-opening by high-pressure water), a vibrowasher, ultrasonic water, mangle or the like. The tension applied to the glass cloth in the fiber-opening processing can be reduced, to thereby result in a tendency to more decrease the air permeability. It is here preferable for suppressing a reduction in the tensile strength of the glass cloth due to the fiber-opening processing that measures such as a reduction in friction of a contact member in weaving of the glass yarn, and optimization of a bundling agent and an increase in attachment thereof be conducted.

There may be included, after the fiber-opening step, an optional step. Examples of such an optional step include, but are not particularly limited to, a slit processing step.

### [Prepreg]

A prepreg of the present embodiment includes the glass cloth, and a matrix resin with which the glass cloth is impregnated. Thus, a prepreg can be provided which is low in dielectric constant, and which achieves an enhancement in insulation reliability due to a decrease in the amount of the hollow yarn and an enhancement in insulation reliability due to an enhancement in moisture absorption resistance.

As the matrix resin, any of a thermosetting resin and a thermoplastic resin can be used. Examples of the thermosetting resin include, but are not particularly limited to, a) an epoxy resin to be cured by a reaction of a compound having an epoxy group, and a compound having at least one of an amino group, a phenol group, an acid anhydride group, a hydrazido group, an isocyanate group, a cyanate group, a hydroxyl group, and the like which reacts with an epoxy group, by addition of no catalyst or a catalyst having a reaction catalytic ability, such as an imidazole compound, a tertiary amine compound, a urea compound, a phosphorus compound or the like; b) a radical polymerization type curing resin to be cured by use of a compound having at least one of an allyl group, a methacrylic group and an acrylic group with a thermal decomposition type catalyst or an optical decomposition type catalyst as a reaction initiator; c) a maleimide triazine resin to be cured by a reaction of a compound having a cyanate group and a compound having a maleimide group; d) a thermosetting polyimide resin to be cured by a reaction of a maleimide compound and an amine compound; and e) a benzoxazine resin to be crosslinked and cured by thermal polymerization of a compound having a benzoxazine ring.

Examples of the thermoplastic resin include, but are not particularly limited to, polyphenylene ether, modified polyphenylene ether, polyphenylene sulfide, polysulfone, polyethersulfone, polyarylate, aromatic polyamide, polyether ether ketone, thermoplastic polyimide, insoluble polyimide, polyamideimide and a fluororesin. In addition, the thermosetting resin and the thermoplastic resin may also be used in combination.

### [Printed Wiring Board]

A printed wiring board of the present embodiment includes the prepreg. Thus, a printed wiring board can be provided which is thin and low in dielectric constant and which achieves an enhancement in insulation reliability due to a decrease in the amount of the hollow yarn and an enhancement in insulation reliability due to an enhancement in moisture absorption resistance.

### EXAMPLES

Next, the present invention is described with reference to Examples and Comparative Examples in more detail. The present invention is not limited to the following Examples at all.

### Example A

### Example A1

A glass cloth (Style 2116: average filament diameter: 7 μm, beating density of the warp yarn: 60/inch, beating density of the weft yarn: 58/inch, thickness: 92 μm) including 21% by mass of B₂O₃ and 56% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.50% by weight. The amount of carbon on the glass cloth was 3.1 mol/cm².

### Example A2

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.26% by weight. The amount of carbon on the glass cloth was 1.1 mol/cm².

### Example A3

A glass cloth (Style 2116: average filament diameter: 7 μm, beating density of the warp yarn: 60/inch, beating density of the weft yarn: 58/inch, thickness: 92 μm) including 29% by mass of B₂O₃ and 51% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.33% by weight. The amount of carbon on the glass cloth was 1.5 mol/cm².

### Example A4

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.90% by weight. The amount of carbon on the glass cloth was 5.5 mol/cm².

### Example A5

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; Z6032) was dispersed in water, and the resultant was heated and dried. Next, fiber-opening by high-pressure water was performed by spray, and the resultant was heated and dried to provide a product. The loss on ignition of the silane coupling agent was 0.55% by weight. The amount of carbon on the glass cloth was 3.3 mol/cm².

### Example A6

A glass cloth (Style 2116: average filament diameter: 7 μm, beating density of the warp yarn: 60/inch, beating density of the weft yarn: 58/inch, thickness: 92 μm) including 23% by mass of B₂O₃ and 53% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; Z6032) was dispersed in water, and the resultant was heated and dried. Next, fiber-opening by high-pressure water was performed by spray, and the resultant was heated and dried to provide a product. The loss on ignition of the silane coupling agent was 0.52% by weight. The amount of carbon on the glass cloth was 3.2 mol/cm².

### Example A7

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which aminopropylethoxysilane (manufactured by Dow Corning Toray Co., Ltd.; Z6011) was dispersed in water, and the resultant was heated and dried. Next, fiber-opening by high-pressure water was performed by spray, and the resultant was heated and dried to provide a product. The loss on ignition of the silane coupling agent was 0.55% by weight. The amount of carbon on the glass cloth was 3.4 mol/cm².

### Example A8

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which aminoethylaminopropyltrimethoxysilane (manufactured by Dow Corning Toray Co., Ltd.; 26020) was dispersed in water, and the resultant was heated and dried. Next, fiber-opening by high-pressure water was performed by spray, and the resultant was heated and dried to provide a product. The loss on ignition of the silane coupling agent was 0.55% by weight. The amount of carbon on the glass cloth was 3.3 mol/cm².

### Comparative Example A1

A glass cloth (Style 2116: average filament diameter: 7 μm, beating density of the warp yarn: 60/inch, beating density of the weft yarn: 58/inch, thickness: 92 μm) including 19% by mass of B₂O₃ and 61% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.26% by weight.

### Comparative Example A2

A glass cloth (Style 2116: average filament diameter: 7 μm, beating density of the warp yarn: 60/inch, beating density of the weft yarn: 58/inch, thickness: 92 μm) including 31% by mass of B₂O₃ and 49% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.26% by weight.

### Comparative Example A3

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.24% by weight. The amount of carbon on the glass cloth was 0.9 mol/cm².

### Comparative Example A4

A glass cloth (Style 2116: average filament diameter: 7 μm, beating density of the warp yarn: 60/inch, beating density of the weft yarn: 58/inch, thickness: 92 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 1.10% by weight. The amount of carbon on the glass cloth was 7.5 mol/cm².

### Comparative Example A5

An E glass cloth (Style 2116: average filament diameter: 7 μm, beating density of the warp yarn: 60/inch, beating density of the weft yarn: 58/inch, thickness: 92 μm) including 7% by mass of B₂O₃ and 54% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.24% by weight.

### <Evaluation Method of Loss on Ignition>

The loss on ignition was measured according to the method described in JIS R3420. The change in weight before and after heating by a muffle furnace was measured, and the loss on ignition was calculated as the amount of the treatment agent attached.

### [Average Filament Diameter of Glass Filaments]

The average filament diameter of the glass filaments was calculated by observing the transverse section of the glass cloth impregnated with the resin and cured, with an electron microscope, measuring the diameters of 25 glass filaments randomly selected, and determining the average of the diameters of the 25 glass filaments as the average filament diameter.

### <Evaluation Method of Amount of Carbon on Glass Cloth>

The glass cloth subjected to surface treatment was heated at about 800° C. for 1 minute, the amount of carbon dioxide in the gas generated was measured by gas chromatography, and the amount of carbon dioxide in the gas generated from the glass cloth heated and desized, subjected to no surface treatment, was subtracted therefrom, thereby determining the number of carbon generated from the surface treatment agent for the glass cloth. The surface area of the glass cloth was calculated from the glass filament diameter, the number of glass filaments and the weaving density of the glass cloth, and the amount (mol/cm²) of carbon on the glass cloth was determined.

### <Evaluation Method of Hollow Yarn>

The glass cloth was observed with an optical microscope from the above while being dipped in an organic solvent (benzyl alcohol) having the same refractive index as that of the glass and irradiated with light, and the number of hollow yarns seen in a single yarn filament was counted. The number of hollow yarns per 100000 single yarn filaments was calculated.

### <Preparation Method of Substrate>

The glass cloth obtained in each of Example A and Comparative Example A was impregnated with an epoxy resin varnish (a mixture of 40 parts by mass of a low-brominated bisphenol A type epoxy resin (manufactured by Mitsubishi Chemical Corporation), 10 parts by mass of an o-cresol type novolac epoxy resin (manufactured by Mitsubishi Chemical Corporation), 50 parts by mass of dimethylformamide, 1 part by mass of dicyandiamide, and 0.1 parts by mass of 2-ethyl-4-methylimidazole), and dried at 160° C. for 2 minutes, and thereafter a prepreg was obtained. The prepreg was stacked, and copper foil having a thickness of 12 μm was further stacked thereon and thereunder, and heated and pressurized at 175° C. and 40 kg/cm² for 60 minutes, thereby providing a substrate.

### <Evaluation Method of Dielectric Constant of Substrate>

A substrate having a thickness of 1 mm was prepared so that the resin content per 100% by mass of the prepreg was 60% by mass, as described above, and the copper foil was removed to provide a sample for dielectric constant evaluation. The dielectric constant of the resulting sample at a frequency of 1 GHz was measured with an impedance analyzer (manufactured by Agilent Technologies).

### <Evaluation Method 1 of Water Absorbability of Substrate>

A substrate having a thickness of 0.4 mm was prepared so that the resin content per 100% by mass of the prepreg was 60% by mass, as described above, and the copper foil was removed to provide a sample for water absorbability evaluation. The resulting sample was first heated in a dryer at 120° C. for 60 minutes, and cooled to room temperature by a desiccator, and thereafter the weight was measured with an electronic balance. Next, the sample was heated and allowed to absorb water in a pressure cooker container at 121° C. for 500 hours, and cooled to room temperature in water, thereafter the water content on the surface thereof was removed, and the weight was measured with an electronic balance. The water absorption rate of the substrate was determined from the change in the weight before and after heating and water absorption.

### <Evaluation Method of Insulation Reliability of Substrate>

A substrate was prepared so that the thickness was 0.4 mm, as described above, and a wiring pattern where a through hole was disposed at a 0.15 mm interval on copper foil on each of both surfaces of the substrate was produced to provide a sample for insulation reliability evaluation. A voltage of 10 V was applied to the resulting sample under an atmosphere of a temperature of 120° C. and a humidity of 85% RH, and the change in resistance value was measured. Here, a case where the resistance reached less than 1 MΩ within 500 hours after the initiation of the test was counted as an insulation failure. The same measurement was performed for 10 of the samples, and the proportion of sample(s) with no insulation failure, in the 10 of the samples, was calculated.

The evaluation results of the number of hollow yarns of the glass cloth shown in each of Examples A1 to 8 and Comparative Examples A1 to 5, and the dielectric constant, the water absorption rate and the insulation reliability of the substrate were summarized in Table 1.

TABLE 1

| | | | Loss on | Number of | | Water | Insulation |
|---|---|---|---|---|---|---|---|
| | | | ignition | hollow yarns | Dielectric | absorption rate | reliability |
| | B₂O₃ | SiO₂ | wt % | ppm | constant | wt % | % |
| Example A1 | 21 | 56 | 0.50 | 0 | 4.2 | 0.9 | 100 |
| Example A2 | 25 | 52 | 0.26 | 0 | 4.2 | 1.1 | 90 |
| Example A3 | 29 | 51 | 0.33 | 0 | 4.2 | 1.2 | 90 |
| Example A4 | 25 | 52 | 0.90 | 0 | 4.2 | 1 | 90 |
| Example A5 | 25 | 52 | 0.55 | 0 | 4.2 | 0.8 | 100 |
| Example A6 | 23 | 53 | 0.52 | 0 | 4.2 | 0.5 | 100 |
| Example A7 | 25 | 52 | 0.55 | 0 | 4.2 | 1.2 | 100 |
| Example A8 | 25 | 52 | 0.55 | 0 | 4.2 | 1 | 100 |
| Comparative | 19 | 61 | 0.26 | 50 | 4.2 | 1 | 0 |
| Example A1 | | | | | | | |
| Comparative | 31 | 49 | 0.26 | 0 | 4.4 | 3.1 | 0 |
| Example A2 | | | | | | | |
| Comparative | 25 | 52 | 0.24 | 0 | 4.2 | 3.5 | 0 |
| Example A3 | | | | | | | |
| Comparative | 25 | 52 | 1.10 | 0 | 4.2 | 1.8 | 10 |
| Example A4 | | | | | | | |
| Comparative | 7 | 54 | 0.24 | 0 | 5.3 | 0.8 | 100 |
| Example A5 | | | | | | | |

It was found that the glass cloth in each of Examples A1 to 8 was low in the dielectric constant, small in the number of hollow yarns, also low in the water absorption rate, and very excellent in the insulation reliability.

### Example B

### Example B1

A glass cloth (Style 1078: average filament diameter: 5 μm, beating density of the warp yarn: 54/inch, beating density of the weft yarn: 54/inch, thickness: 46 μm) including 21% by mass of B₂O₃ and 56% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 5 μm, and the tensile strength in the warp yarn direction of the glass cloth was 130 N/inch.

### Example B2

A glass cloth (Style 1078: average filament diameter: 5 μm, beating density of the warp yarn: 54/inch, beating density of the weft yarn: 54/inch, thickness: 46 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; Z6032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 5 μm, and the tensile strength in the warp yarn direction of the glass cloth was 120 N/inch.

### Example B3

A glass cloth (Style 1078: average filament diameter: 5 μm, beating density of the warp yarn: 54/inch, beating density of the weft yarn: 54/inch, thickness: 46 μm) including 29% by mass of B₂O₃ and 51% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 5 μm, and the tensile strength in the warp yarn direction of the glass cloth was 100 N/inch.

### Example B4

A glass cloth (Style 1078: average filament diameter: 5 μm, beating density of the warp yarn: 54/inch, beating density of the weft yarn: 54/inch, thickness: 44 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; Z6032) was dispersed in water, and the resultant was heated and dried. Next, fiber-opening by high-pressure water (water pressure: 13 kgf/cm², tension in fiber-opening processing: 100 N) was performed by spray, and the resultant was heated and dried to provide a product. The air permeability of the glass cloth was 29 cm³/cm²/sec, the average filament diameter was 5 μm, and the tensile strength in the warp yarn direction of the glass cloth was 90 N/inch.

### Example B5

A glass cloth (Style 1078: average filament diameter: 5 μm, beating density of the warp yarn: 54/inch, beating density of the weft yarn: 54/inch, thickness: 43 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 15 kgf/cm², tension in fiber-opening processing: 100 N) was performed by spray, and the resultant was heated and dried to provide a product. The air permeability of the glass cloth was 8 cm³/cm²/sec, the average filament diameter was 5 μm, and the tensile strength in the warp yarn direction of the glass cloth was 80 N/inch.

### Example B6

A glass cloth (Style 3313: average filament diameter: 6 μm, beating density of the warp yarn: 60/inch, beating density of the weft yarn: 62/inch, thickness: 73 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 6 μm, and the tensile strength in the warp yarn direction of the glass cloth was 160 N/inch.

### Comparative Example B1

A glass cloth (Style 1078: average filament diameter: 5 μm, beating density of the warp yarn: 54/inch, beating density of the weft yarn: 54/inch, thickness: 46 μm) including 19% by mass of B₂O₃ and 61% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 5 μm, and the tensile strength in the warp yarn direction of the glass cloth was 140 N/inch.

### Comparative Example B2

A glass cloth (Style 1078: average filament diameter: 5 μm, beating density of the warp yarn: 54/inch, beating density of the weft yarn: 54/inch, thickness: 46 μm) including 31% by mass of B₂O₃ and 49% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 10 kgf/cm², tension in fiber-opening processing: 100 N) was performed by spray, and the resultant was heated and dried to provide a product. The air permeability of the glass cloth was 45 cm³/cm²/sec, the average filament diameter was 5 μm, and the tensile strength in the warp yarn direction of the glass cloth was 80 N/inch.

### Comparative Example B3

A glass cloth (Style 1078: average filament diameter: 5 μm, beating density of the warp yarn: 54/inch, beating density of the weft yarn: 54/inch, thickness: 46 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; Z6032) was dispersed in water, and the resultant was heated and dried. Next, fiber-opening by high-pressure water (water pressure: 5 kgf/cm², tension in fiber-opening processing: 100 N) was performed by spray, and the resultant was heated and dried to provide a product. The air permeability of the glass cloth was 55 cm³/cm²/sec, the average filament diameter was 5 μm, and the tensile strength in the warp yarn direction of the glass cloth was 150 N/inch.

### Comparative Example B4

A glass cloth (Style 1078: average filament diameter: 5 μm), beating density of the warp yarn: 54/inch, beating density of the weft yarn: 54/inch, thickness: 46 μm) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 5 kgf/cm², tension in fiber-opening processing: 300 N) was performed by spray, and the resultant was heated and dried to provide a product. The air permeability of the glass cloth was 90 cm³/cm²/sec, the average filament diameter was 5 μm, and the tensile strength in the warp yarn direction of the glass cloth was 160 N/inch.

### Comparative Example B5

An E glass cloth (Style 1078: average filament diameter: 5 μm, beating density of the warp yarn: 54/inch, beating density of the weft yarn: 54/inch, thickness: 46 μm) including 7% by mass of B₂O₃ and 54% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water (water pressure: 5 kgf/cm², tension in fiber-opening processing: 100 N) was performed by spray, and the resultant was heated and dried to provide a product. The air permeability of the glass cloth was 55 cm³/cm²/sec, the average filament diameter was 5 μm, and the tensile strength in the warp yarn direction of the glass cloth was 160 N/inch.

### [Tensile Strength of Glass Cloth]

The tensile strength of the glass cloth was measured according to Section 7.4 of JIS R 3420.

### [Average Filament Diameter of Glass Filaments]

The average filament diameter of the glass filaments was calculated by observing the transverse section of the glass cloth impregnated with the resin and cured, with an electron microscope, measuring the diameters of 25 glass filaments randomly selected, and determining the average of the diameters of the 25 glass filaments as the average filament diameter.

### [Method of Measuring Air Permeability]

The air permeability of the glass cloth was measured according to JIS R3420.

### <Evaluation Method of Hollow Yarn>

The glass cloth was observed with an optical microscope from the above while being dipped in an organic solvent (benzyl alcohol) having the same refractive index as that of the glass and irradiated with light, and the number of hollow yarns seen in a single yarn filament was counted. The number of hollow yarns per 100000 single yarn filaments was calculated.

### <Preparation Method of Laminate>

The glass cloth obtained in each of Example B and Comparative Example B was impregnated with an epoxy resin varnish (a mixture of 40 parts by mass of a low-brominated bisphenol A type epoxy resin (manufactured by Mitsubishi Chemical Corporation), 10 parts by mass of an o-cresol type novolac epoxy resin (manufactured by Mitsubishi Chemical Corporation), 50 parts by mass of dimethylformamide, 1 part by mass of dicyandiamide, and 0.1 parts by mass of 2-ethyl-4-methylimidazole), and dried at 160° C. for 2 minutes, and thereafter a prepreg was obtained. The prepreg was stacked, and copper foil having a thickness of 12 μm was further stacked thereon and thereunder, and heated and pressurized at 175° C. and 40 kg/cm² for 60 minutes, thereby providing a laminate.

### <Evaluation Method of Dielectric Constant of Laminate>

A laminate was prepared so that the thickness was 1 mm, as described above, and the copper foil was removed to provide a sample for dielectric constant evaluation. The dielectric constant of the resulting sample at a frequency of 1 GHz was measured with an impedance analyzer (manufactured by Agilent Technologies).

### <Evaluation Method of Laser Processability of Laminate>

A laminate was prepared so that the thickness was 0.2 mm, as described above, and the copper foil was removed to produce 100 through holes having a diameter of 100 μm by a carbon dioxide laser processing machine LC-2G212/2C. Furthermore, the resultant was subjected to desmear treatment and plating treatment, thereafter the cross section of each of the through holes was observed with an optical microscope, and the average of the plating permeation length into each of the through holes was evaluated.

### <Evaluation Method of Insulation Reliability of Laminate>

A laminate was prepared so that the thickness was 0.4 mm, as described above, and a wiring pattern where a through hole was disposed at a 0.15 mm interval on copper foil on each of both surfaces of the laminate was produced to provide a sample for insulation reliability evaluation. A voltage of 10 V was applied to the resulting sample under an atmosphere of a temperature of 120° C. and a humidity of 85% RH, and the change in resistance value was measured. Here, a case where the resistance reached less than 1 MO within 500 hours after the initiation of the test was counted as an insulation failure. The same measurement was performed for 10 of the samples, and the proportion of sample(s) with no insulation failure, in the 10 of the samples, was calculated.

The evaluation results of the number of hollow yarns of the glass cloth shown in each of Examples B1 to 6 and Comparative Examples B1 to 5, and the dielectric constant, the plating permeation length and the insulation reliability of the laminate were summarized in Table 2.

TABLE 2

| | | | | | | Plating | |
|---|---|---|---|---|---|---|---|
| | | | Air | Number of | | permeation | Insulation |
| | | | permeability | hollow yarns | Dielectric | length | reliability |
| | B₂O₃ | SiO₂ | cm³/cm²/second | ppm | constant | μm | % |
| Example B1 | 21 | 56 | 45 | 0 | 4.2 | 25 | 100 |
| Example B2 | 25 | 52 | 45 | 0 | 4.2 | 27 | 100 |
| Example B3 | 29 | 51 | 45 | 0 | 4.2 | 30 | 90 |
| Example B4 | 25 | 52 | 29 | 0 | 4.2 | 15 | 100 |
| Example B5 | 25 | 52 | 8 | 0 | 4.2 | 5 | 100 |
| Example B6 | 25 | 52 | 45 | 0 | 4.2 | 55 | 90 |
| Comparative | 19 | 61 | 45 | 21 | 4.2 | 25 | 0 |
| Example B1 | | | | | | | |
| Comparative | 31 | 49 | 45 | 0 | 4.4 | 80 | 0 |
| Example B2 | | | | | | | |
| Comparative | 25 | 52 | 55 | 0 | 4.2 | 130 | 10 |
| Example B3 | | | | | | | |
| Comparative | 25 | 52 | 90 | 0 | 4.2 | 250 | 0 |
| Example B4 | | | | | | | |
| Comparative | 7 | 54 | 55 | 0 | 5.3 | 5 | 100 |
| Example B5 | | | | | | | |

It was found that the glass cloth in each of Examples B1 to 6 was low in dielectric constant, small in the number of hollow yarns, also good in the laser processability, and very excellent in the insulation reliability.

### Example C

### Example C1

A glass cloth (Style 1067: average diameter of glass filament: 5 μm, beating density of the warp yarn: 70/inch, beating density of the weft yarn: 70/inch, thickness: 30 μm, mass: 28 g/m²) including 21% by mass of B₂O₃ and 56% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C2

A glass cloth (Style 1067: average diameter of glass filament: 5 μm, beating density of the warp yarn: 70/inch, beating density of the weft yarn: 70/inch, thickness: 30 μm, mass: 28 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C3

A glass cloth (Style 1067: average diameter of glass filament: 5 μm, beating density of the warp yarn: 70/inch, beating density of the weft yarn: 70/inch, thickness: 30 μm, mass: 28 g/m²) including 29% by mass of B₂O₃ and 51% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C4

A glass cloth (Style 1067: average diameter of glass filament: 5 μm, beating density of the warp yarn: 70/inch, beating density of the weft yarn: 70/inch, thickness: 30 μm, mass: 28 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.75% by weight.

### Example C5

A glass cloth (Style 1067: average diameter of glass filament: 5 μm, beating density of the warp yarn: 70/inch, beating density of the weft yarn: 70/inch, thickness: 30 μm, mass: 28 g/m²) including 23% by mass of B₂O₃ and 53% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.90% by weight.

### Example C6

A glass cloth (Style 1067: average diameter of glass filament: 5 μm, beating density of the warp yarn: 70/inch, beating density of the weft yarn: 70/inch, thickness: 30 μm, mass: 28 g/m²) including 25% by mass of B₂O₃ and 52% by mass of SiO₂ was dipped in a treatment liquid in which aminopropyltriethoxysilane (manufactured by Dow Corning Toray Co., Ltd.; 26011) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C7

A glass cloth (Style 1067: average diameter of glass filament: 5 μm, beating density of the warp yarn: 70/inch, beating density of the weft yarn: 70/inch, thickness: 30 μm, mass: 28 g/m²) including 25% by mass of B₂O₃ and 52% by mass of SiO₂ was dipped in a treatment liquid in which aminoethylaminopropyltrimethoxysilane (manufactured by Dow Corning Toray Co., Ltd.; 26020) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C8

A glass cloth (Style 1037: average diameter of glass filament: 4.5 μm, beating density of the warp yarn: 70/inch, beating density of the weft yarn: 73/inch, thickness: 25 μm, mass: 20 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.65% by weight.

### Example C9

A glass cloth (Style 1027: average diameter of glass filament: 4 μm, beating density of the warp yarn: 75/inch, beating density of the weft yarn: 75/inch, thickness: 20 μm, mass: 17 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.75% by weight.

### Example C10

A glass cloth (Style 3313: average diameter of glass filament: 6 μm, beating density of the warp yarn: 60/inch, beating density of the weft yarn: 62/inch, thickness: 73 μm, mass: 72 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Example C11

A glass cloth (Style 3313: average diameter of glass filament: 6 μm, beating density of the warp yarn: 60/inch, beating density of the weft yarn: 62/inch, thickness: 73 μm, mass: 72 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.45% by weight.

### Comparative Example C1

A glass cloth (Style 1067: average diameter of glass filament: 5 μm, beating density of the warp yarn: 70/inch, beating density of the weft yarn: 70/inch, thickness: 30 μm, mass: 28 g/m²) including 19% by mass of B₂O₃ and 61% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Comparative Example C2

A glass cloth (Style 1067: average diameter of glass filament: 5 μm, beating density of the warp yarn: 70/inch, beating density of the weft yarn: 70/inch, thickness: 30 μm, mass: 28 g/m²) including 31% by mass of B₂O₃ and 49% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.51% by weight.

### Comparative Example C3

A glass cloth (Style 1067: average diameter of glass filament: 5 μm, beating density of the warp yarn: 70/inch, beating density of the weft yarn: 70/inch, thickness: 30 μm, mass: 28 g/m²) including 25% by mass of B₂O₃ and 52% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 1.10% by weight.

### Comparative Example C4

An E glass cloth (Style 1067: average diameter of glass filament: 5 μm, beating density of the warp yarn: 70/inch, beating density of the weft yarn: 70/inch, thickness: 30 μm, mass: 28 g/m²) including 7% by mass of B₂O₃ and 54% by mass of SiO₂ was dipped in a treatment liquid in which N-β-(N-vinylbenzylaminoethyl)-γ-aminopropyltrimethoxysilane hydrochloride (manufactured by Dow Corning Toray Co., Ltd.; 26032) was dispersed in water, and the resultant was heated and dried. Next, fiber-opening by high-pressure water was performed by spray, and the resultant was heated and dried to provide a product. The loss on ignition of the silane coupling agent was 0.45% by weight.

### <Evaluation Method of Loss on Ignition>

The loss on ignition was measured according to the method described in JIS R3420. The change in weight before and after heating by a muffle furnace was measured, and the loss on ignition was calculated as the amount of the treatment agent attached.

### <Evaluation Method of Hollow Yarn>

The glass cloth was observed with an optical microscope from the above while being dipped in an organic solvent (benzyl alcohol) having the same refractive index as that of the glass and irradiated with light, and the number of hollow yarns seen in a single yarn filament was counted. The number of hollow yarns per 100000 single yarn filaments was calculated.

### <Preparation Method of Substrate>

The glass cloth obtained in each of Examples and Comparative Examples was impregnated with an epoxy resin varnish (a mixture of 40 parts by mass of a low-brominated bisphenol A type epoxy resin (manufactured by Mitsubishi Chemical Corporation), 10 parts by mass of an o-cresol type novolac epoxy resin (manufactured by Mitsubishi Chemical Corporation), 50 parts by mass of dimethylformamide, 1 part by mass of dicyandiamide, and 0.1 parts by mass of 2-ethyl-4-methylimidazole), and dried at 160° C. for 2 minutes, and thereafter a prepreg was obtained. The prepreg was stacked, and copper foil having a thickness of 12 μm was further stacked thereon and thereunder, and heated and pressurized at 175° C. and 40 kg/cm² for 60 minutes, thereby providing a substrate.

### <Evaluation Method of Dielectric Constant of Substrate>

A substrate was prepared so that the resin content per 100% by mass of the prepreg was 60% by mass, as described above, and the copper foil was removed to provide a sample for dielectric constant evaluation. The dielectric constant of the resulting sample at a frequency of 1 GHz was measured with an impedance analyzer (manufactured by Agilent Technologies).

### <Evaluation Method of Water Absorption Rate of Substrate>

A substrate was prepared so that the resin content per 100% by mass of the prepreg was 60% by mass, as described above, and the copper foil was removed to provide a sample for water absorption rate evaluation. The resulting sample was first dried in a dryer at 120° C. for 1 hour, and cooled to room temperature by a desiccator, and thereafter the weight was measured with an electronic balance. Next, the sample was placed in a pressure cooker at 121° C. and 2 bar for 168 hours and allowed to absorb water, and finally the water content on the surface of the sample was removed and thereafter the weight of the sample was measured with an electronic balance. The water absorption rate was calculated from the change in the weight.

### <Evaluation Method of Insulation Reliability of Substrate>

A substrate was prepared so that the thickness was 0.4 mm, as described above, and a wiring pattern where a through hole was disposed at a 0.15 mm interval on copper foil on each of both surfaces of the substrate was produced to provide a sample for insulation reliability evaluation. A voltage of 10 V was applied to the resulting sample under an atmosphere of a temperature of 120° C. and a humidity of 85% RH, and the change in resistance value was measured. Here, a case where the resistance reached less than 1 MΩ within 500 hours after the initiation of the test was counted as an insulation failure. The same measurement was performed for 10 of the samples, and the proportion of sample(s) with no insulation failure, in the 10 of the samples, was calculated.

The evaluation results of the glass cloth shown in each of Examples C1 to 11 and Comparative Examples C1 to 4 were summarized in Table 3.

TABLE 3

| | | | | Average | | | | |
|---|---|---|---|---|---|---|---|---|
| | | | | diameter | Number | | Water | |
| | | | Loss on | of glass | of hollow | | absorption | Insulation |
| | | | ignition | filaments | yarns | Dielectric | rate | reliability |
| | B₂O₃ | SiO₂ | wt % | μm | ppm | constant | wt % | % |
| Example C1 | 21 | 56 | 0.51 | 5 | 0 | 4.2 | 1.1 | 100 |
| Example C2 | 25 | 52 | 0.51 | 5 | 0 | 4.2 | 1.3 | 90 |
| Example C3 | 29 | 51 | 0.51 | 5 | 0 | 4.2 | 1.5 | 90 |
| Example C4 | 25 | 52 | 0.75 | 5 | 0 | 4.2 | 0.7 | 100 |
| Example C5 | 23 | 53 | 0.90 | 5 | 0 | 4.2 | 0.6 | 100 |
| Example C6 | 25 | 52 | 0.51 | 5 | 0 | 4.2 | 1.4 | 100 |
| Example C7 | 25 | 52 | 0.51 | 5 | 0 | 4.2 | 1.2 | 100 |
| Example C8 | 25 | 52 | 0.65 | 4.5 | 0 | 4.2 | 1.0 | 100 |
| Example C9 | 25 | 52 | 0.75 | 4 | 0 | 4.2 | 1.0 | 100 |
| Example C10 | 25 | 52 | 0.51 | 6 | 0 | 4.2 | 1.1 | 100 |
| Example C11 | 25 | 52 | 0.45 | 6 | 0 | 4.2 | 1.2 | 90 |
| Comparative | 19 | 61 | 0.51 | 5 | 40 | 4.2 | 1.2 | 0 |
| Example C1 | | | | | | | | |
| Comparative | 31 | 49 | 0.51 | 5 | 0 | 4.4 | 3.5 | 0 |
| Example C2 | | | | | | | | |
| Comparative | 25 | 52 | 1.10 | 5 | 0 | 4.2 | 2.2 | 10 |
| Example C3 | | | | | | | | |
| Comparative | 7 | 54 | 0.45 | 5 | 0 | 5.3 | 1.0 | 100 |
| Example C4 | | | | | | | | |

It was found that the glass cloth in each of Examples C1 to 12 was thin, low in the dielectric constant, and very excellent in the insulation reliability.

The present application is based on the Japanese Patent Application (Japanese Patent Application No. 2015-090518) filed with Japan Patent Office on Apr. 27, 2015, the Japanese Patent Application (Japanese Patent Application No. 2015-140410) filed with Japan Patent Office on Jul. 14, 2015, and the Japanese Patent Application (Japanese Patent Application No. 2016-001188) filed with Japan Patent Office on Jan. 6, 2016, the contents of which are herein incorporated by reference.

### INDUSTRIAL APPLICABILITY

The glass cloth of the present invention is industrially applicable as a substrate for use in a printed wiring board used in the electronic and electrical fields.

1. A glass cloth obtained by weaving a glass yarn comprising a plurality of glass filaments, wherein a compositional amount of B₂O₃ is 20% by mass to 30% by mass in the glass filaments and a compositional amount of SiO₂ is 50% by mass to 60% by mass in the glass filaments, and a loss on ignition of the glass cloth is 0.25% by mass to 1.0% by mass.

2. The glass cloth according to claim 1, wherein the loss on ignition of the glass cloth is 0.3% by mass to 0.9% by mass.

3. The glass cloth according to claim 1, wherein the loss on ignition of the glass cloth is 0.35% by mass to 0.8% by mass.

4. The glass cloth according to claim 1, wherein an average filament diameter of the glass filaments is 5 μm or less, and the loss on ignition of the glass cloth is 0.5% by mass to 1.0% by mass.

5. The glass cloth according to claim 1, wherein an air permeability of the glass cloth is 50 cm³/cm²/sec or less.

6. The glass cloth according to claim 1, wherein a tensile strength of the glass cloth is 20 N/inch or more.

7. The glass cloth according to claim 1, wherein an amount of carbon on the glass cloth is 1 mol/cm² or more.

8. The glass cloth according to claim 1, wherein the glass cloth is subjected to a surface-treatment with a silane coupling agent represented by the following general formula (1):
X(R)₃₋ₙSiYₙ (1)
wherein X represents an organic functional group having one or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.

9. The glass cloth according to claim 1, wherein the glass cloth is subjected to a surface-treatment with a silane coupling agent represented by the following general formula (2):
X(R)₃₋ₙSiYₙ (2)
wherein X represents an organic functional group having three or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.

10. The glass cloth according to claim 1, wherein the glass cloth is subjected to a surface-treatment with a silane coupling agent represented by the following general formula (3):
X(R)₃₋ₙSiYₙ (3)
wherein X represents an organic functional group having four or more of at least any of an amino group and an unsaturated double bond group, each Y independently represents an alkoxy group, n represents an integer of 1 or more and 3 or less, and each R independently represents a group selected from the group consisting of a methyl group, an ethyl group and a phenyl group.

11. A prepreg comprising the glass cloth according to claim 1, and a matrix resin with which the glass cloth is impregnated.

12. A printed wiring board comprising the prepreg according to claim 11.
